(19) United States
(12) Patent Application Publication
(10) Pub. No.: US 2020/0081083 A1
(43) Pub. Date: Mar. 12, 2020

(54) SYSTEMS AND METHODS FOR CRYOCOOLER THERMAL MANAGEMENT

(71) Applicant: General Electric Company, Schenectady, NY (US)

(72) Inventors: Ali Ok, Florence, SC (US); Haixia Xi, Florence, SC (US); Stuart Paul Feltham, Florence, SC (US); Mark Derakhshan, Florence, SC (US)

(21) Appl. No.: 16/126,701

(22) Filed: Sep. 10, 2018

(51) Int. Cl. G01R 33/38; F25D 19/00; H01F 6/04; G01R 33/3815

(52) U.S. Cl. CPC G01R 33/3804; G01R 33/3815; H01F 6/04; F25D 19/006

(57) ABSTRACT

A thermal management system is provided that includes a cold-head cryocooler and a cooling jacket. The cold-head cryocooler is configured to be operably coupled to a helium vessel of an MRI system, and is configured to cool at least one of superconducting magnets or a thermal shield of the MRI system. The cooling jacket has an outer surface defining a sleeve exterior, and includes a pathway disposed radially internally of the sleeve exterior defined by the cooling jacket. The cooling jacket is configured to receive boil-off gas from the helium vessel to be circulated through the pathway to cool the cold-head cryocooler.

### BACKGROUND OF THE INVENTION

The subject matter disclosed herein relates generally to apparatus and methods for cooling of an MRI system, such as during powered off periods of the MRI system.

For cryogenically cooled MR magnets, helium used for cooling the magnets may evaporate when a system including the MR magnets is powered off. For example, the system may be powered off for transportation from one location to a different location. When the system is powered off, the helium may warm and vaporize, resulting in loss of helium.

### BRIEF DESCRIPTION OF THE INVENTION

In one example embodiment, a thermal management system is provided that includes a cold-head cryocooler and a cooling jacket. The cold-head cryocooler is configured to be operably coupled to a helium vessel of an MRI system, and is configured to cool at least one of superconducting magnet coils or a thermal shield of the MRI system. The cooling jacket has an outer surface defining a sleeve exterior, and includes a pathway disposed radially internally of the sleeve exterior defined by the cooling jacket. The cooling jacket is configured to receive boil-off gas from the helium vessel to be circulated through the pathway to cool the cold-head cryocooler.

In another example embodiment, a method is provided that includes coupling a cold-head cryocooler configured to a helium vessel of an MRI system. The cold-head cryocooler is configured to cool at least one of superconducting magnets or a thermal shield of the MRI system. The method also includes providing a cooling jacket disposed about at least a portion of the cold-head cryocooler. The cooling jacket has an outer surface defining a sleeve exterior, and includes a pathway disposed radially internally of the exterior defined by the cooling jacket. The cooling jacket is configured to receive boil-off gas from the helium vessel to be circulated through the pathway to cool the cold-head cryocooler.

In another example embodiment, a thermal management system is provided that includes a cold-head cryocooler and a cooling member. The cold-head cryocooler is configured to be operably coupled to a helium vessel of an MRI system, and is configured to cool at least one of superconducting magnets or a thermal shield of the MRI system. The cooling member is coupled to the cold-head cryocooler and includes a pathway configured to receive boil-off gas from the helium vessel to be circulated through the pathway to cool the cold-head cryocooler. The pathway includes an interior cross-section.

### BRIEF DESCRIPTION OF THE DRAWINGS

FIG. 1 provides a schematic view of a thermal management system in accordance with various embodiments.

FIG. 2 provides a side view of aspects of a thermal management system in accordance with various embodiments.

FIG. 3a provides a side sectional view of a cold-head sleeve in accordance with various embodiments.

FIG. 3b provides an enlarged view of a portion of FIG. 3a.

FIG. 4 provides a side sectional view of a cold-head sleeve in accordance with various embodiments.

FIG. 5a provides a sectional view of a passageway in accordance with various embodiments.

FIG. 5b provides a sectional view of a passageway in accordance with various embodiments.

FIG. 5c provides a sectional view of a passageway in accordance with various embodiments.

FIG. 5d provides a sectional view of a passageway in accordance with various embodiments.

FIG. 5e provides a sectional view of a passageway in accordance with various embodiments.

FIG. 5f provides a sectional view of a passageway in accordance with various embodiments.

FIG. 5g provides a sectional view of a passageway in accordance with various embodiments.

FIG. 6 provides a side view of aspects of a thermal management system in accordance with various embodiments.

FIG. 7 provides a perspective view of a thermal management system in accordance with various embodiments.

FIG. 8 provides a flowchart of a method in accordance with various embodiments.

FIG. 9 provides a schematic block diagram of an MRI system in accordance with various embodiments.

### DETAILED DESCRIPTION OF THE INVENTION

The following detailed description of certain embodiments will be better understood when read in conjunction with the appended drawings. To the extent that the figures illustrate diagrams of the functional blocks of various embodiments, the functional blocks are not necessarily indicative of the division between hardware. It should be understood that the various embodiments are not limited to the arrangements and instrumentality shown in the drawings.

As used herein, an element or step recited in the singular and preceded with the word “a” or “an” should be understood as not excluding plural of said elements or steps, unless such exclusion is explicitly stated. Furthermore, references to “one embodiment” of are not intended to be interpreted as excluding the existence of additional embodiments that also incorporate the recited features. Moreover, unless explicitly stated to the contrary, embodiments “comprising” or “having” an element or a plurality of elements having a particular property may include additional elements not having that property.

Various embodiments provide systems and methods for improving cooling of MRI systems and/or reducing helium loss during the power off situation of the cold head cryocooler such as MRI system transportation or cold head malfunctioning. Various embodiments provide use of a cold head sleeve having a passageway for boil-off gas to improve operation of a cold-head cryocooler. Various embodiments utilize traditional manufacturing such as welding and brazing or non-conventional manufacturing such as additive manufacturing to provide a heat exchanger cross-section for a cold head sleeve (or other passageway, such as an outer tube). In various embodiments, boil-off gas is used to cool a cold head sleeve (e.g., first stage of a cold head sleeve) using a heat exchanger on the sleeve body. Additionally or alternatively, various embodiments utilize insulation around portions of a cold head cryocooler extending beyond a housing. Various embodiments receive boil-off gas from a helium vessel to be circulated through a pathway to cool a cold-head cryocooler and associated cryocooler sleeve by intercepting the heat from outside, which can result in reduced helium lost.

A technical embodiment of various embodiments includes improved cooling of MRI systems (e.g., during powered off conditions). A technical embodiment of various embodiments includes reduced helium loss during powered off conditions, and reduced cost to refill helium in a helium vessel.

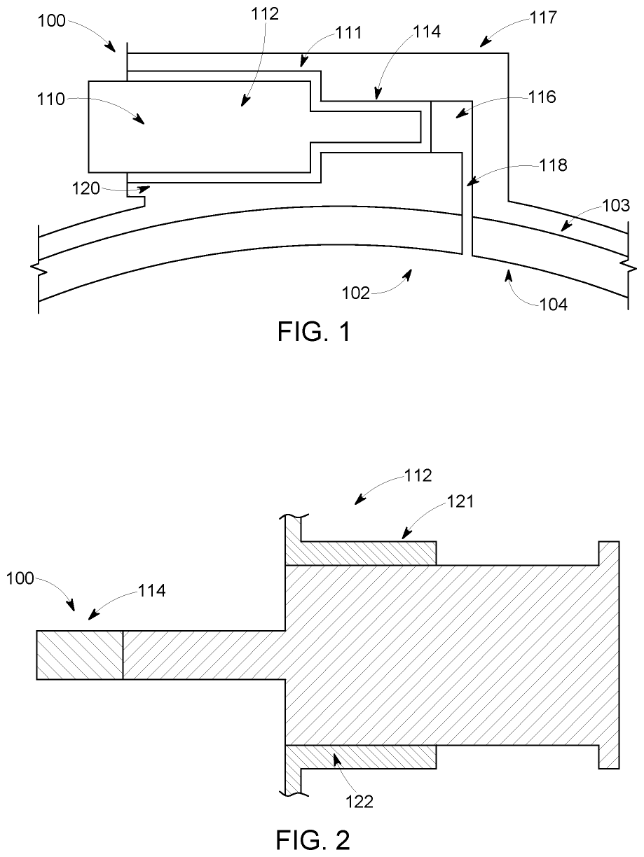

FIG. 1 provides a perspective view of a thermal management system 100 formed in accordance with various embodiments. The thermal management system 100 includes a cold-head cryocooler 110 and a cooling member 120. The depicted thermal management system 100 is operably coupled to a helium vessel 104 of a magnetic resonance imaging (MRI) system 102. Generally, the thermal management system 100 is used to cool aspects of the MRI system 102 (e.g., at least one of superconducting magnets or a thermal shield 103 of the MRI system 102) during power off condition of the system (e.g., during a power-off condition of a cryocooler of magnets of the MRI system).

In various embodiments, the coils on superconducting magnets of the MRI system 102 are cryogenically cooled using the helium vessel 104. During operation of the cold-head cryocooler 110, the cold-head cryocooler 110 (which may be disposed within a sleeve) functions to recondense vaporized cryogen to continually cool the superconducting magnet coils and/or thermal shield 103 of the MRI system 102. For example, the vaporized cryogen may be supplied to a recondenser 116 via a conduit 118. During the use of the cold-head cryocooler 110, a cold head sleeve 111 acts as a vacuum barrier between a vacuum chamber and external environment to preserve a vacuum seal. A housing 117 in the illustrated embodiment is disposed about a portion of the cold-head cryocooler 110 and cooperates with the cold head sleeve 111 to provide a vacuum.

As seen in FIG. 1, the depicted cryocooler 110 includes a first stage 112 and a second stage 114. The first stage 112 may have a higher operating temperature than the second stage 114. For example, the first stage may have an operating temperature of about 40 degrees Kelvin, and the second stage 114 may have an operating temperature of about 4 degrees Kelvin.

Generally, the cooling member 120 is configured to receive boil-off gas from the helium vessel 104, and to act as a heat exchanger using the boil-off gas to cool the cold-head cryocooler 110 (e.g., by cooling a sleeve surrounding the cryocooler). For example, in various embodiments the cooling member 120 includes a pathway configured to receive boil-off gas from the helium vessel 104 to be circulated through the pathway to cool the cold-head cryocooler 110. In various embodiments, the pathway has an interior cross-section configured to act as a heat exchanger. Various different manufacturing techniques may be employed to form the cross-section. As one example, the interior cross-section may be formed by additive manufacturing (e.g., 3D printing). For example, additive manufacturing may be employed to provide complex internal shapes to direct boil-off gas flow that are not possible or practical with other manufacturing techniques. In other embodiments, the interior cross section may be formed by alternate manufacturing techniques, such as welding, brazing, or casting.

The cooling member 120 is schematically depicted as a block in FIG. 1; however, it may be noted that in various embodiments the cooling member is a generally tubular structure that surrounds all or a portion of the cold-head cryocooler 110. For example, the cooling member may include a cylindrical sleeve that surrounds all or a portion of the cold-head cryocooler 110, and/or may include tubing that surrounds (e.g., is helically wound around) all or a portion of the cold-head cryocooler 110.

In various embodiments, the cooling member 120 is configured as a cooling sleeve or jacket. The cooling jacket in various embodiments defines a generally cylindrically shaped structure having an inner wall and outer wall extending along a length of the cold-head cryocooler and surrounding the cold-head cryocooler, with the pathway that receives the boil-off gas extending in the volume between the inner wall and the outer wall. The outer wall and inner wall may each define a continuous cylindrical surface. For example, FIG. 2 provides a perspective view of an embodiment of the thermal management system 100 that includes a cooling jacket 122. The cooling jacket 122 is an example of a cooling member 120. In various embodiments, the cooling jacket 122 forms a portion of the cold-head sleeve 111. For example, in some embodiments the cooling jacket 122 may be integrally formed with the cold-head sleeve 111, or may be joined thereto.

The depicted cooling jacket 122 includes an outer surface 124 that defines a sleeve exterior 126. Also, the depicted cooling jacket 122 includes a pathway 128 disposed radially inwardly of the sleeve exterior 126 defined by the cooling jacket 122 (e.g., defined by the outer surface 124). The cooling jacket 122 is configured to receive boil-off gas from the helium vessel 104 to be circulated through the pathway 128 to cool the cold-head cryocooler. In the illustrated embodiment, the cooling jacket 122 includes access ports 121 that may be used as inlets and outlets for the boil-off gas. It may be noted that the access ports can be in any shape and orientation. In various embodiments, the cooling jacket is made of a thermally conductive metal, such as aluminum, copper, or stainless steel, by way of example. It may be noted that in various embodiments, the cooling jacket 122 (or aspects thereof) may be built by any type of non-conventional and conventional manufacturing methods.

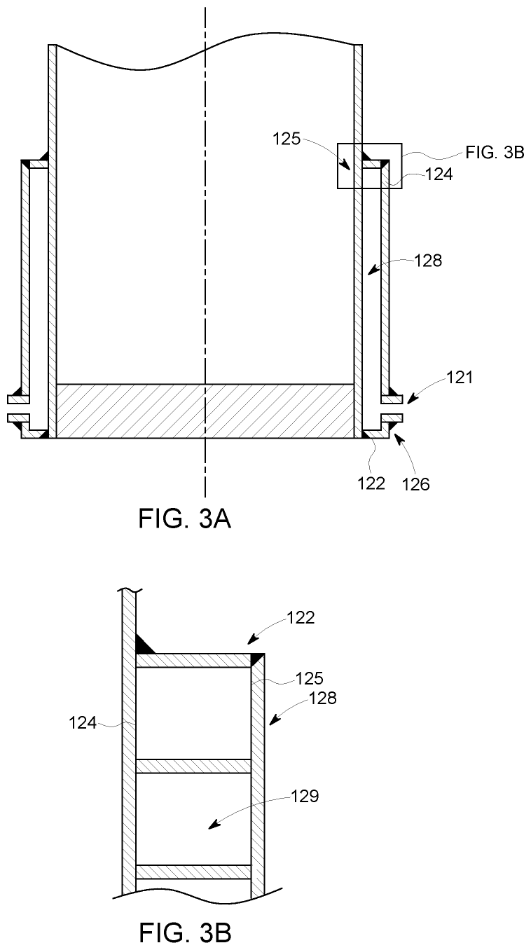

FIG. 3a provides a side-sectional view of the cooling jacket 122, and FIG. 3b provides an enlarged view of a portion of FIG. 3a. As best seen in FIG. 3a or 3b, the cooling jacket 122 includes an inner surface 125 spaced a distance from the outer surface 124 to define a volume through which the pathway 128 passes. Accordingly, fluid (e.g., boil-off gas) passing through the pathway 128 may be used to remove heat from the cryocooler disposed radially inwardly from the inner surface 125. In the illustrated embodiment, channels 129 are defined in the space between the inner surface 125 and outer surface 124 to form the pathway. The channels 129 may cooperate to form the pathway 128, and/or one or more additional pathways. During manufacturing other structures may be disposed in the space between the inner surface 125 and outer surface 124 to define the channels 129 and/or to guide the flow through the passageway 128.

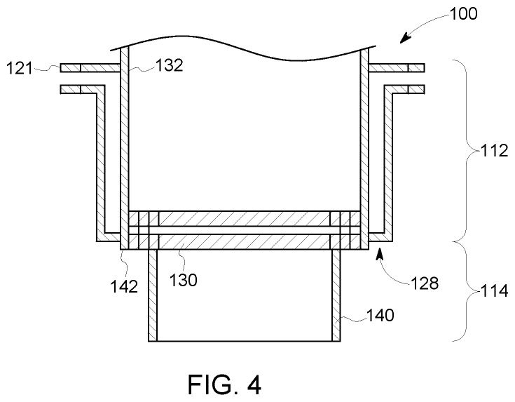

In various embodiments, the cooling jacket 122 may be disposed about the first stage 112 (or portions thereof) and/or the second stage 114 (or portions thereof). For example, FIG. 4 illustrates a side-sectional view of an embodiment in which the cooling jacket 122 (which includes a pathway 128 for the flow of boil-off gas) is disposed about the first stage 112. As seen in FIG. 4, the thermal management system 100 of the depicted example also includes an adaptor plate 130 and a second stage sleeve 140. The adaptor plate 130 may be formed as a ring providing an interface between the second stage sleeve 140 and the cooling jacket 122. In the illustrated example, the cooling jacket 122 is configured to be disposed about the first stage 112, and the second stage sleeve 140 is configured to be disposed about the second stage 114. The adaptor plate 130 is configured to join the cooling jacket 122 with the second stage sleeve 140. For example, a first stage pipe 132 may be joined with the second stage sleeve 140 with the adaptor plate 130, and the cooling jacket 122 disposed about the first stage pipe 132. The first stage assembly or components (cooling jacket and first stage pipe 132) may be joined to the adaptor plate 130 and second stage 140, for example, by brazing, welding, or additive fabrication.

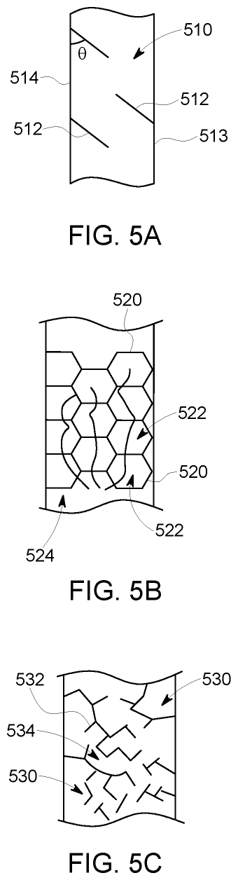

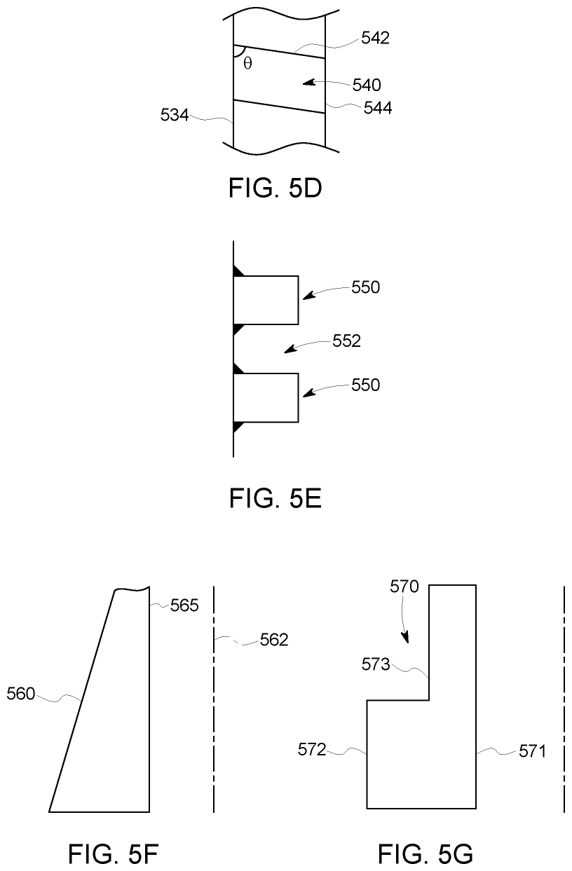

As discussed above, in various embodiments, the pathway 128 (or aspects thereof) may be formed in various embodiments to provide complex interior shapes between the inner surface 125 and outer surface 124 of the cooling jacket, or to provide complex interior shapes within an interior of tubing wrapped around one or more aspects of the cold-head cryocooler 110. As one example, additive manufacturing may be utilized to help provide complex passageways for improved thermal performance in various embodiments. Other manufacturing techniques may be used additionally or alternatively in various embodiments. FIGS. 5a-5g illustrate examples of passageway shapes formed in accordance with various embodiments, with the passageways configured to act as heat exchangers in various embodiments.

FIG. 5a illustrates an example in which the pathway 128 defines an open pathway 510 that does not include channels. Instead, the open pathway 510 includes extensions 512 that are cantilevered from either the inner surface 513 or the outer surface 514 (e.g., extensions 512 extend from one of the inner surface 513 or outer surface 514 without reaching the other of the inner surface 513 or outer surface 514). The extensions in various embodiments may be in other structural form and/or disposed at different angles.

FIG. 5b illustrates an example in which a cross-section of the pathway 128 defines a honeycomb arrangement. As seen in FIG. 5b, honeycomb walls 520 cooperate to define honeycomb cells 522. In some embodiments, the honeycomb cells may be closed laterally and joined in a helical arrangement. In the illustrated embodiments, the honeycomb cells 522 include openings 524 allowing lateral flow between adjacent honeycomb cells 522.

FIG. 5c illustrates an example in which a cross-section of the pathway 128 defines an open-cell arrangement. The open cell arrangement includes cells 530 defined by walls 532 having openings 534 allowing flow between adjacent cells.

FIG. 5d illustrates an example in which the pathway 128 is formed by continuous helix of closed cells 540 (e.g. fins 542 extending from the inner surface 543 to the outer surface 544). FIG. 5e illustrates an example in which the pathway 128 is formed by an intermittent helix of closed cells 550 (through which boil-off gas flows) spaced apart by spaces 552 through which boil-off gas does not flow. The angles between the walls of the cells can vary among different embodiments.

It may be noted that the inner surface 125 and/or outer surface 124 of the cooling jacket 122 need not necessarily by straight. For example, FIG. 5f illustrates an example embodiment in which the outer surface 560 is tapered along an axis 562 extending along a length of the cooling jacket 122. Additionally or alternatively, the inner surface 565 may be tapered. FIG. 5g illustrates an example embodiment in which the outer surface 570 is stepped, having a first portion 572 that is farther from the inner surface 571 than a second portion 573 is from the inner surface 571. It may be noted, with reference to FIGS. 5a-5g, that the illustrated examples are provided by way of example, and that variations of the illustrated example, combinations of the various example, or other arrangements may be utilized in various embodiments. The particular configuration (e.g., size, arrangement, or the like) may be selected for the particular heat exchange requirements of a given application.

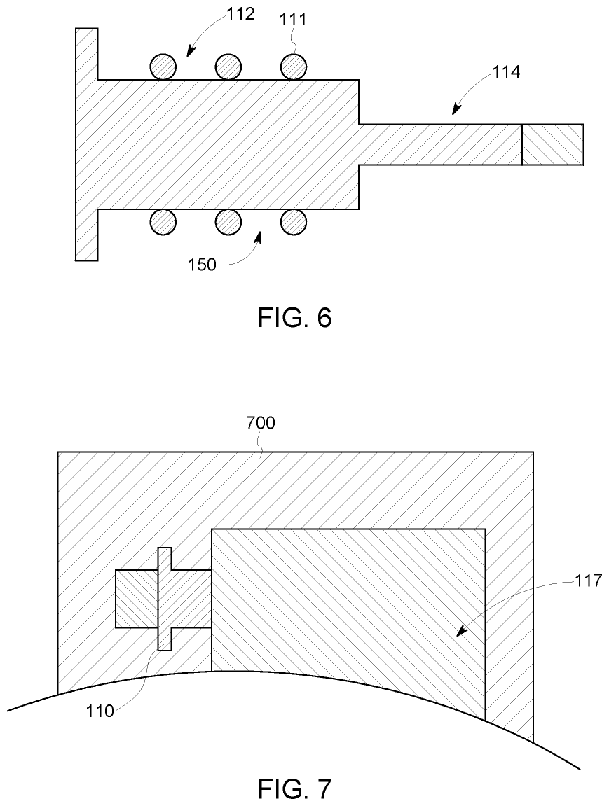

Additionally or alternatively to a sleeve including a pathway for boil-off gas radially inward of an exterior of the sleeve, in various embodiments a pathway for boil-off gas may be provided via a tube disposed radially outward of the exterior of the sleeve. For example, FIG. 6 provides a side view of an example of the thermal management system 100 in which the cooling member 120 includes an outer tube 150. In the illustrated example, the outer tube 150 is disposed around the sleeve exterior 126 of the cold head sleeve 111. It may be noted that the outer tube 150 may be placed around the cold head sleeve 111 at either or both of the first stage 112 or second stage 114 (or portions thereof). Further, it may be noted that the outer tube 150 may be disposed within a vacuum defined by the housing 117 and/or outside of the vacuum defined by the housing 117 in various embodiments. The outer tube 150 is configured to receive boil-off gas from the helium vessel 104 (e.g., the pathway 128 extends through the interior of the outer tube). In various embodiments, the outer tube 150 has an additively manufacture internal structure (e.g., the honeycomb arrangement of FIG. 5b, the open cell arrangement of FIG. 5c). Other manufacturing techniques may be used in various embodiments. In various embodiments, the outer tube 150 may be disposed about the cooling jacket 122.

Additionally or alternatively to the sleeves and tubes discussed in connection with FIGS. 2-6, in various embodiments the thermal management system includes insulation. FIG. 7 provides a perspective view of the thermal management system 100 in which insulation 700 (represented by hatched lines) is provided around at least a portion of an exterior of the cold-head cryocooler 110. In the illustrated example, the insulation is provided around the portion of the cold-head cryocooler 110 that is outside of the housing 117. For example, a temporary cover may be disposed about cold-head cryocooler 110 outside of the housing 117, insulation 700 introduced into the temporary cover to fill the space between the temporary cover and the cold-head cryocooler 110, and the cover removed.

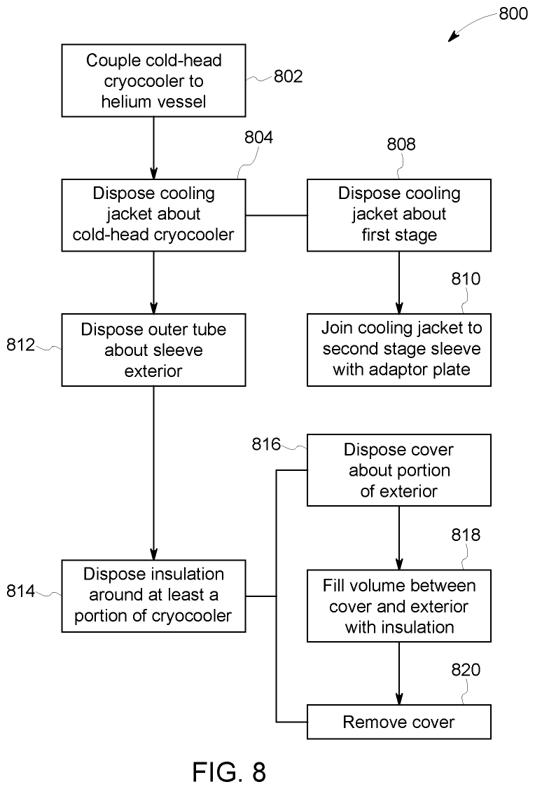

FIG. 8 provides a flowchart of a method 800. The method 800 (or aspects thereof), for example, may employ or be performed by structures or aspects of various embodiments (e.g., systems and/or methods and/or process flows) discussed herein. In various embodiments, certain steps may be omitted or added, certain steps may be combined, certain steps may be performed concurrently, certain steps may be split into multiple steps, certain steps may be performed in a different order, or certain steps or series of steps may be re-performed in an iterative fashion.

At 802, a cold-head cryocooler (e.g., cold-head cryocooler 110) is coupled to a helium vessel of an MRI system (e.g., helium vessel 104 of MRI system 102). The cold-head cryocooler is configured to cool at least one of superconducting magnets or a thermal shield of the MRI system. For example, the cold-head cryocooler may be used to cool vaporized cryogen which is then returned to the helium vessel. The cold-head cryocooler may be coupled to the helium vessel mechanically and fluidly, either directly or indirectly. For example, the cold-head cryocooler may be indirectly mounted mechanically to the helium vessel by being mounted to a structure that is in turn mounted to the helium vessel. The cold-head cryocooler is fluidly coupled to the helium vessel (e.g., via a conduit) to receive vaporized cryogen from the helium vessel.

At 804, a cooling jacket (e.g., cooling jacket 122) is disposed about at least a portion of the cold-head cryocooler. The cooling jacket has an outer surface that defines a sleeve exterior, and includes a pathway disposed radially inwardly of the sleeve exterior. (See, e.g., FIGS. 3a and 3b.) The cooling jacket is configured to receive boil-off gas from the helium vessel to be circulated through the pathway to cool the cold-head cryocooler. It may be noted that other cooling members (e.g., an outer tube such outer tube 150) and/or insulation may be utilized as discussed herein may be used additionally or alternatively in various embodiments.

In various embodiments, the cooling jacket includes a pathway formed or defined to act as a heat exchanger. In some embodiments, the pathway is formed using using additive manufacturing. In some embodiments, an open pathway devoid of channels is formed. In some embodiments, the pathway is additively manufactured to have a cross-section defining a honeycomb arrangement. As one more example, in some embodiments, the pathway is additively manufactured to have a cross-section defining an open-cell arrangement.

As discussed herein, the cooling jacket in various embodiments is disposed about a first stage of the cold-head cryocooler. In the illustrated example, at 808, the cooling jacket is disposed about the first stage. For example, at 810, the cooling jacket is joined to a second stage sleeve (e.g., second stage sleeve 140) with an adaptor plate (e.g., adaptor plate 130).

At 812, an outer tube (e.g., outer tube 150) is disposed about the sleeve exterior of the cooling jacket. The outer tube is configured to receive boil-off gas from the helium vessel and has an additively manufactured internal structure to define a pathway through which the boil-off gas flows. It may be noted that in some embodiments, the outer tube may be used alternatively to a cooling sleeve as discussed herein. Generally, the outer tube is wrapped in a helical fashion about an exterior of a cold-head sleeve. The outer may be wrapped about a first stage (or portions thereof) and/or a second stage (or portions thereof) of the cold-head cryocooler in various embodiments.

At 814, of the illustrated embodiment, insulation is disposed around at least a portion of the exterior of the cold-head cryocooler. (See, e.g., FIG. 7 and related discussion.) The insulation may be in contact with and surround an exterior of the cold-head cryocooler. It may be noted that the use of insulation may be employed alternatively or additionally to the use of a cooling jacket and/or outer tube in various embodiments. In the depicted example, at 816, a cover is disposed about the portion of the exterior of the cold-head cryocooler to be insulated (e.g., about the portion of the cold-head cryocooler outside of a housing defining a vacuum chamber). The cover defines a volume between the cover and the exterior of the cold-head cryocooler. At 818, the volume between the cover and exterior is filled with insulation, and at 820, the cover is removed. For example, in some embodiments, a liquid polyurethane insulation may be provided, or insulation may be provided in a bag which is placed around the exterior of the cold-head cryocooler (more than one bag may be used in various embodiments). The cover may then provide a temporary enclosure while the insulation is injected and allowed to cure.

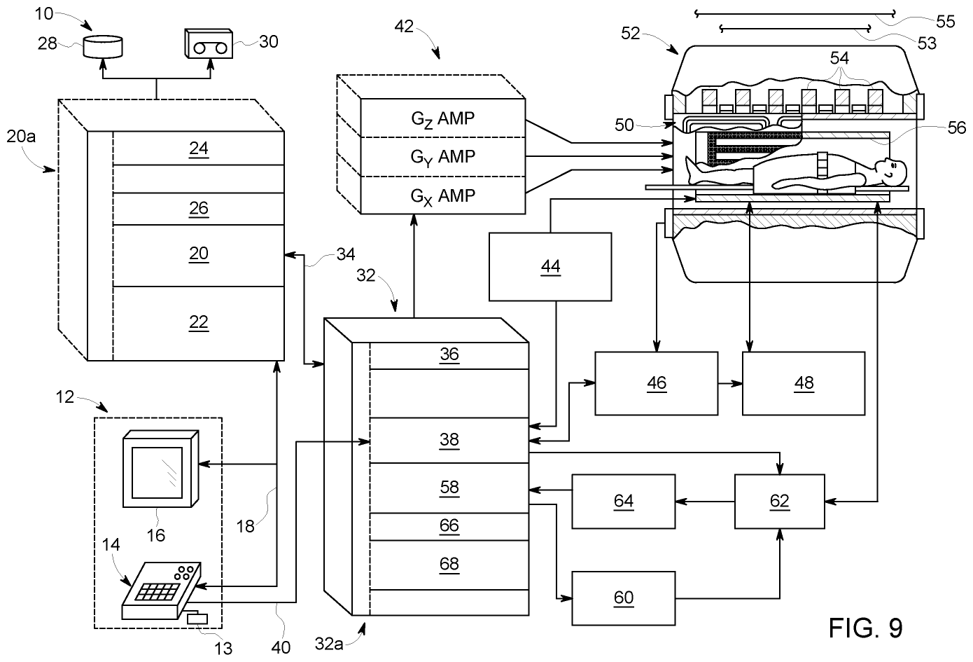

As discussed herein various methods and/or systems (and/or aspects thereof) described herein may be implemented in connection with an MRI system. For example, FIG. 9 depicts various major components of an MRI system 10 formed in accordance with various embodiments. The operation of the system is controlled from an operator console 12 which includes a keyboard or other input device 13, a control panel 14, and a display 16. The console 12 communicated through a link 18 with a separate computer system 20 that enables an operator to control the production and display of images on the screen 16. The computer system 20 includes a number of modules which communicate with each other through a backplane 20a. These include an image processor module 22, a CPU module 24 and a memory module 26, known in the art as a frame buffer for storing image data arrays. The computer system 20 is linked to disk storage 28 and tape drive 30 for storage of image data and programs, and communicates with a separate system control 32 through a high speed serial link 34. The input device 13 can include a mouse, joystick, keyboard, track ball, touch activated screen, light want, voice control, or any similar or equivalent input device, and may be used for interactive geometry prescription.

The system control 32 includes a set of modules connected together by a backplane 32a. These include a CPU module 36 and a pulse generator module 38 which connects to the operator console 12 through a serial link 40. It is through link 40 that the system control 32 receives commands from the operator to indicate the san sequence that is to be performed. The pulse generator module 38 operates the system components to carry out the desired scan sequence and produce data which indicates the timing, strength and shape of the RF pulses produced, and the timing and length of the data acquisition window. The pulse generator module 38 connects to a set of gradient amplifiers 42, to indicate the timing and shape of the gradient pulses that are produced during the scan. The pulse generator module 38 can also receive patient data from a physiological acquisition controller 44 that receives signals from a number of different sensor connected to the patient or subject, such as ECG signals from electrodes attached to the patient. And finally, the pulse generator module 38 connects to a scan room interface circuit 46 which receives signals from various sensors associated with the condition of the patient and the magnet system. It is also through the scan room interface circuit 46 that a patient positioning system 48 receives commands to move the patient to the desired position for the scan.

The gradient waveforms produced by the pulse generator module 38 are applied to the gradient amplifier system 42 having Gₓ, G_{y}, and G_{z} amplifiers. Each gradient amplifier excites a corresponding physical gradient coil in a gradient coil assembly generally designated 50 to produce the magnetic field gradients used for spatially encoding acquired signals. The gradient coil assembly 50 and RF shield (not shown) form a part of a magnet assembly 52 which includes a polarizing magnet 54 and a RF coil assembly 56. A transceiver module 58 in the system control 32 produces pulses which are amplified by an RF amplifier 60 and coupled to the RF coil assembly 56 by a transmit/receive switch 62. The resulting signals emitted by the excited nuclei in the patient may be sensed by the same RF coil assembly 56 or apportion thereof and coupled through transmit/receive switch 62 to a preamplifier 64. The amplified MR signals are demodulated, filtered, and digitized in the receive section of the transceiver 58. The transmit/receive switch 62 is controlled by a signal from the pulse generator module 38 to electrically connect the RF amplifier 60 to the coil assembly 56 during the transmit mode and to connect the preamplifier 64 to the coil assembly 56 during the receive mode. The transmit/receive switch 62 can also enable a separate RF coil (for example, a surface coil) to be used in either the transmit or receive mode. The magnet assembly 52 may be cooled cryogenically. For example, the magnet assembly 52 of the depicted embodiment is disposed within a helium vessel 53 that utilizes helium to cryogenically cool the magnet assembly 52. A thermal shield 55 is also disposed about the magnet assembly 52.

The MR signals picked up by the selected RF coil are digitized by the transceiver module 58 and transferred to a memory module 66 in the system control 32. A scan is complete when an array of raw k-space data has been acquired in the memory module 66. This raw k-space data is rearranged into separate k-space data arrays for each image to be reconstructed, and each of these is input to an array processor 68 which operates to Fourier transform the data into an array of image data. This image data is conveyed through the serial link 34 to the computer system 20 where it is stored in memory, such as disk storage 28. In response to commands received from the operator console 12, this image data may be archived in long term storage, such as on the tape drive 30, or it may be further processed by the image processor 22 and conveyed to the operator console 12 and presented on the display 16.

It should be noted that the various embodiments may be implemented in hardware, software or a combination thereof. The various embodiments and/or components, for example, the modules, or components and controllers therein, also may be implemented as part of one or more computers or processors. The computer or processor may include a computing device, an input device, a display unit and an interface, for example, for accessing the Internet. The computer or processor may include a microprocessor. The microprocessor may be connected to a communication bus. The computer or processor may also include a memory. The memory may include Random Access Memory (RAM) and Read Only Memory (ROM). The computer or processor further may include a storage device, which may be a hard disk drive or a removable storage drive such as a solid-state drive, optical disk drive, and the like. The storage device may also be other similar means for loading computer programs or other instructions into the computer or processor.

As used herein, the term “computer” or “module” may include any processor-based or microprocessor-based system including systems using microcontrollers, reduced instruction set computers (RISC), ASICs, logic circuits, and any other circuit or processor capable of executing the functions described herein. The above examples are exemplary only, and are thus not intended to limit in any way the definition and/or meaning of the term “computer”.

The computer or processor executes a set of instructions that are stored in one or more storage elements, in order to process input data. The storage elements may also store data or other information as desired or needed. The storage element may be in the form of an information source or a physical memory element within a processing machine.

The set of instructions may include various commands that instruct the computer or processor as a processing machine to perform specific operations such as the methods and processes of the various embodiments. The set of instructions may be in the form of a software program. The software may be in various forms such as system software or application software and which may be embodied as a tangible and non-transitory computer readable medium. Further, the software may be in the form of a collection of separate programs or modules, a program module within a larger program or a portion of a program module. The software also may include modular programming in the form of object-oriented programming. The processing of input data by the processing machine may be in response to operator commands, or in response to results of previous processing, or in response to a request made by another processing machine.

As used herein, a structure, limitation, or element that is “configured to” perform a task or operation is particularly structurally formed, constructed, or adapted in a manner corresponding to the task or operation. For purposes of clarity and the avoidance of doubt, an object that is merely capable of being modified to perform the task or operation is not “configured to” perform the task or operation as used herein. Instead, the use of “configured to” as used herein denotes structural adaptations or characteristics, and denotes structural requirements of any structure, limitation, or element that is described as being “configured to” perform the task or operation. For example, a processing unit, processor, or computer that is “configured to” perform a task or operation may be understood as being particularly structured to perform the task or operation (e.g., having one or more programs or instructions stored thereon or used in conjunction therewith tailored or intended to perform the task or operation, and/or having an arrangement of processing circuitry tailored or intended to perform the task or operation). For the purposes of clarity and the avoidance of doubt, a general purpose computer (which may become “configured to” perform the task or operation if appropriately programmed) is not “configured to” perform a task or operation unless or until specifically programmed or structurally modified to perform the task or operation.

As used herein, the terms “software” and “firmware” are interchangeable, and include any computer program stored in memory for execution by a computer, including RAM memory, ROM memory, EPROM memory, EEPROM memory, and non-volatile RAM (NVRAM) memory. The above memory types are exemplary only, and are thus not limiting as to the types of memory usable for storage of a computer program.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the various embodiments without departing from their scope. While the dimensions and types of materials described herein are intended to define the parameters of the various embodiments, they are by no means limiting and are merely exemplary. Many other embodiments will be apparent to those of skill in the art upon reviewing the above description. The scope of the various embodiments should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112(f) unless and until such claim limitations expressly use the phrase “means for” followed by a statement of function void of further structure.

This written description uses examples to disclose the various embodiments, including the best mode, and also to enable any person skilled in the art to practice the various embodiments, including making and using any devices or systems and performing any incorporated methods. The patentable scope of the various embodiments is defined by the claims, and may include other examples that occur to those skilled in the art. Such other examples are intended to be within the scope of the claims if the examples have structural elements that do not differ from the literal language of the claims, or the examples include equivalent structural elements with insubstantial differences from the literal language of the claims.

What is claimed is:

1. A thermal management system comprising:
a cold-head cryocooler configured to be operably coupled to a helium vessel of a magnetic resonance imaging (MRI) system, the cold-head cryocooler configured to cool at least one of superconducting magnets or a thermal shield of the MRI system;
a cooling jacket having an outer surface defining a sleeve exterior, the cooling jacket including a pathway disposed radially inwardly of the sleeve exterior defined by the cooling jacket, the cooling jacket configured to receive boil-off gas from the helium vessel to be circulated through the pathway to cool at least one of the cold-head cryocooler or a cryocooler sleeve.

2. The thermal management system of claim 1, wherein the cold-head cryocooler comprises a first stage and a second stage, wherein the cooling jacket is disposed about at least one of the first stage or the second stage.

3. The thermal management system of claim 2, further comprising an adaptor plate and a second stage sleeve, the adaptor plate configured to join the cooling jacket with the second stage sleeve.

4. The thermal management system of claim 1, wherein the pathway defines an open pathway without channels.

5. The thermal management system of claim 1, wherein a cross-section of the pathway defines a honeycomb arrangement.

6. The thermal management system of claim 1, wherein a cross-section of the pathway defines an open-cell arrangement.

7. The thermal management system of claim 1, further comprising an outer tube disposed around the sleeve exterior of the cooling jacket, the outer tube configured to receive boil-off gas from the helium vessel, the outer tube having an internal structure configured to act as a heat exchanger.

8. The thermal management system of claim 1, further comprising insulation surrounding at least a portion of an exterior of the cold-head cryocooler.

9. A method comprising:
coupling a cold-head cryocooler configured to a helium vessel of an MRI system, the cold-head cryocooler configured to cool at least one of superconducting magnets or a thermal shield of the MRI system;
providing a cooling jacket disposed about at least a portion of the cold-head cryocooler, the cooling jacket having an outer surface defining a sleeve exterior, the cooling jacket including a pathway disposed radially inwardly of the exterior defined by the cooling jacket, the cooling jacket configured to receive boil-off gas from the helium vessel to be circulated through the pathway to cool the cold-head cryocooler.

10. The method of claim 9, wherein the cold-head cryocooler comprises a first stage and a second stage, the method comprising disposing the cooling jacket about the first stage and/or the second stage.

11. The method of claim 10, wherein the cold-head cryocooler comprises an adaptor plate and a second stage sleeve, the method comprising joining the cooling jacket to the second stage sleeve via the adaptor plate.

12. The method of claim 9, further comprising additively manufacturing an open pathway without channels within the pathway.

13. The method of claim 9, further comprising additively manufacturing the pathway to have a cross-section defining a honeycomb arrangement.

14. The method of claim 9, further comprising additively manufacturing the pathway to have a cross-section defining an open-cell arrangement.

15. The method of claim 9, further comprising disposing an outer tube around the sleeve exterior of the cooling jacket, the outer tube configured to receive boil-off gas from the helium vessel, the outer tube having an internal structure.

16. The method of claim 9, further comprising disposing insulation around at least a portion of an exterior of the cold-head cryocooler.

17. The method of claim 16, further comprising disposing a cover about the at least a portion of the exterior of the cold-head cooler with a volume defined between the cover and the exterior of the cold-head cryocooler, filling the volume with the insulation, and removing the cover.

18. A thermal management system comprising:
a cold-head cryocooler configured to be operably coupled to a helium vessel of an MRI system, the cold-head cryocooler configured to cool at least one of superconducting magnets or a thermal shield of the MRI system;
a cooling member coupled to the cold-head cryocooler, the cooling member including a pathway configured to receive boil-off gas from the helium vessel to be circulated through the pathway to cool the cold-head cryocooler, wherein the pathway comprises an interior cross-section configured to act as a heat exchanger.

19. The thermal management system of claim 18, wherein the cooling member comprises a cooling jacket having an outer surface defining a sleeve exterior, the pathway disposed in the cooling jacket and radially internally of the sleeve exterior defined by the cooling jacket.

20. The thermal management system of claim 18, wherein the cold-head cryocooler includes a cooling jacket having an outer surface defining a sleeve exterior, wherein the cooling member comprises an outer tube disposed around the sleeve exterior of the cooling jacket, the pathway disposed in the outer tube, the outer tube configured to receive the boil-off gas from the helium vessel.
